(19) United States
(12) Patent Application Publication
(10) Pub. No.: US 2020/0080193 A1
(43) Pub. Date: Mar. 12, 2020

(54) CARRIER PLATE FOR EVAPORATING DEVICE AND EVAPORATING DEVICE THEREOF

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Zhen WANG, Beijing (CN); CHUN CHIEH HUANG, Beijing (CN); Zhiming LIN, Beijing (CN); Shouhua LV, Beijing (CN)

(21) Appl. No.: 16/330,903

(22) PCT Filed: Jan. 4, 2018
(86) PCT No.: PCT/CN2018/071297

§ 371 Date: Mar. 6, 2019

(30) Foreign Application Priority Data
May 23, 2017 (CN) 201710368763.5

(51) Int. Cl. C23C 14/50; H01L 51/56; H01L 51/00; C23C 14/24

(52) U.S. Cl. CPC C23C 14/50; C23C 14/24; H01L 51/001; H01L 51/56

(57) ABSTRACT

The present disclosure provides a carrier plate for an evaporating device and an evaporating device thereof. The carrier plate includes a substrate including a groove on a surface of a side, for carrying a member to be evaporated, of the substrate, and a cooler disposed within the groove, wherein the cooler protrudes outward from the surface of the substrate.

### CROSS REFERENCE TO RELATED APPLICATIONS

This patent application is a National Stage Entry of PCT/CN2018/071297 filed on Jan. 4, 2018, which claims the benefit and priority of Chinese Patent Application No. 201710368763.5 filed on May 23, 2017, the disclosures of which are incorporated by reference herein in their entirety as part of the present application.

### BACKGROUND

Embodiments of the present disclosure relate to the field of evaporating technology, and more particularly, to a carrier plate for an evaporating device and an evaporating device thereof.

Organic Light Emitting Diode (OLED) technology has the advantages of high luminous efficiency, low manufacturing cost, wider color gamut, etc., and has become a potential technology to replace liquid crystal display technology. During the process of manufacturing the OLED, evaporating is performed by using a vacuum evaporation coating method (abbreviated as a vacuum evaporation method). In the vacuum evaporation method, the evaporating material is heated by an evaporating source in a vacuum evaporation chamber, such that atoms or molecules of an evaporating material are vaporized from the surface thereof to form a vapor flow which is then incident on a surface of a member to be evaporated and is formed as a solid film. Vacuum evaporation method has been widely applied to the manufacturing process of display device, such as a cathode, an anode, and a layer of luminescent material between the cathode and the anode of an OLED display panel.

### BRIEF DESCRIPTION

Embodiments of the present disclosure provide a carrier plate for an evaporating device and an evaporating device thereof.

A first aspect of the present disclosure provides a carrier plate for an evaporating device. The carrier plate includes a substrate including a groove on a surface of a side, for carrying a member to be evaporated, of the substrate, and a cooler disposed within the groove, wherein the cooler protrudes outward from the surface of the substrate.

In an embodiment of the present disclosure, a cross-sectional shape of the groove in a direction perpendicular to an extending direction of the groove may be a rectangle.

In an embodiment of the present disclosure, the groove may extend in an S-shape.

In an embodiment of the present disclosure, the groove extends uniformly throughout the surface of the substrate in a zigzag way.

In an embodiment of the present disclosure, the carrier plate may further include an elastic element located between the cooler and a bottom of the groove.

In an embodiment of the present disclosure, the elastic element may include a spring.

In an embodiment of the present disclosure, a cross-sectional shape of the cooler in a direction perpendicular to an extending direction of the cooler may be a rectangle or a circle.

In an embodiment of the present disclosure, the cooler may be a cooling tube.

A second aspect of the present disclosure provides an evaporating device including the carrier plate described in the first aspect of the present disclosure.

In an embodiment of the present disclosure, the member to be evaporated may be a glass substrate.

Further aspects and regions of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a schematic plan view of a carrier plate for an evaporating device in accordance with an embodiment of the present disclosure;

FIG. 2 is a cross-sectional view of the carrier plate taken along line AA′ of FIG. 1 in accordance with an embodiment of the present disclosure;

FIG. 3 is a cross-sectional view of the carrier plate taken along line BB′ of FIG. 1 in accordance with an embodiment of the present disclosure; and

FIG. 4 is a cross-sectional view of the carrier plate taken along line BB′ of FIG. 1 in accordance with another embodiment of the present disclosure.

Corresponding reference numerals indicate corresponding parts or features throughout the several views of the drawings.

### DETAILED DESCRIPTION

As used herein and in the appended claims, the singular form of a word includes the plural, and vice versa, unless the context clearly dictates otherwise. Thus, the references “a”, “an”, and “the” are generally inclusive of the plurals of the respective terms. Similarly, the words “comprise”, “comprises”, and “comprising” are to be interpreted inclusively rather than exclusively. Likewise, the terms “include”, “including” and “or” should all be construed to be inclusive, unless such a construction is clearly prohibited from the context. Where used herein the term “examples,” particularly when followed by a listing of terms is merely exemplary and illustrative, and should not be deemed to be exclusive or comprehensive.

In addition, it should be noted that, in the description of the present disclosure, the orientations or positions relationship indicated by the terms “upper”, “above”, “lower”, “under”, “top”, “bottom”, “between”, etc. are the orientations or positions relationship based on the orientations or positions relationship shown in the drawings, which is merely for the convenience of describing the present disclosure and simplifying the description, and does not indicate or imply that the referred device or element has to have a specific orientation and is constructed and operated in a specific orientation, therefore, it can't be understood as a limitation to the disclosure. In addition, when an element or a layer is referred to as being “on” another element or layer, the element or the layer can be directly on the another element or layer, or an intermediate element or layer can be present; likewise, when an element or a layer is referred to as being “under” another element or layer, the element or the layer can be directly under another element or layer, or at least one intermediate element or layer can be present; when an element or a layer is referred to as being between two elements or two layers, the element or the layer can be an unique element or layer between the two elements or the two layers, or more than one intermediate element or layer can be present.

Additionally, further to be noted, when the elements and the embodiments thereof of the present disclosure are introduced, the articles “a/an”, “one”, “the” and “said” are intended to represent the existence of one or more elements. Unless otherwise specified, “a plurality of” means two or more. The expressions “comprise”, “include”, “contain” and “have” are intended as inclusive and mean that there may be other elements besides those listed. The terms such as “first” and “second” are used herein only for purposes of description and are not intended to indicate or imply relative importance and the order of formation.

Example embodiments will now be described more fully with reference to the accompanying drawings.

In an embodiment of the present disclosure, a carrier plate for an evaporating device is provided. The carrier plate has a groove on a surface of a side, for carrying a member to be evaporated, of the carrier plate, wherein a cooler is disposed within the groove, the cooler protruding outward from the carrying surface of the carrier plate, which can reduce the contacting area of the carrier plate with the member to be evaporated, thereby reducing the generation of static electricity.

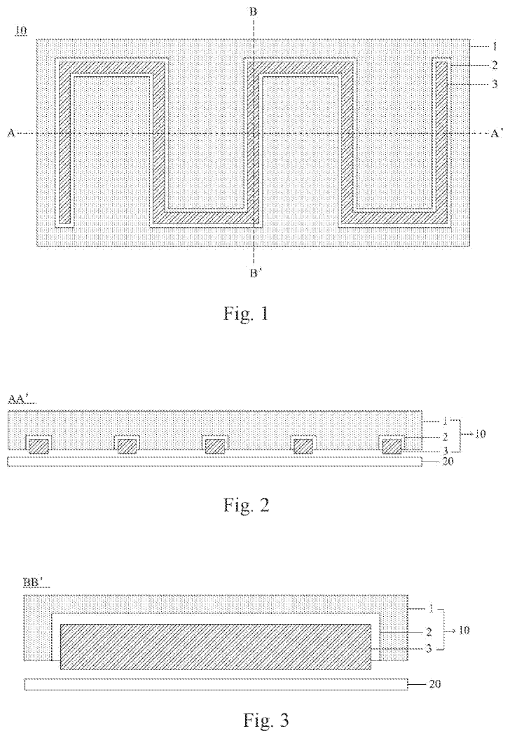

FIG. 1 is a schematic plan view of a carrier plate 10 for an evaporating device in accordance with an embodiment of the present disclosure. As shown in FIG. 1, the carrier plate 10 includes a substrate 1, a groove 2 on a surface of a side, for carrying a member to be evaporated (not shown), of the substrate 1, and a cooler 3 disposed within the groove 2. In an exemplary embodiment, the member to be evaporated may be a glass substrate. In an exemplary embodiment, the groove 2 extends continuously in an S-shape, and the groove extends uniformly throughout the carrying surface of the substrate in a zigzag way. It should be noted that the extending shape of the groove 2 can also be designed according to actual needs. In an exemplary embodiment, a depth of the groove 2 is not particularly limited, as long as a bottom surface of the groove 2 has a certain distance from a non-carrying surface of the substrate 1.

FIG. 2 is a cross-sectional view of the carrier plate 10 taken along line AA′ of FIG. 1 in accordance with an embodiment of the present disclosure. FIG. 3 is a cross-sectional view of the carrier plate 10 taken along line BB′ of FIG. 1 in accordance with an embodiment of the present disclosure. It should be noted that the cross-sectional view shown in FIG. 2 is a cross-sectional view taken along a direction perpendicular to the extending direction of the groove, and the cross-sectional view shown in FIG. 3 is a cross-sectional view taken along the extending direction of the groove. For facilitating to illustrate the embodiments of the present disclosure, both FIGS. 2 and 3 show the member to be evaporated 20 disposed opposite the carrying surface of the carrier plate 10. The carrier plate 10 carries the member to be evaporated 20 thereon and serves to cool the member to be evaporated 20.

As shown in FIGS. 2 and 3, the size of the cooler 3 in the direction from the bottom of the groove 2 toward the outside is not particularly limited, as long as the cooler 3 protrudes outward from the carrying surface of the substrate 1. In an exemplary embodiment, the degree of protrusion is not specifically limited without affecting the flatness and deformation of the member to be evaporated 20, as long as the member to be evaporated 20 can be brought into contact only with the cooler 3 and the contacting area is as small as possible.

In an exemplary embodiment, a cross-sectional shape of the groove 2 in a direction perpendicular to the extending direction of the groove is a rectangle.

In an exemplary embodiment, a cross-sectional shape of the cooler 3 in a direction perpendicular to a direction along which the cooler extends is a rectangle or a circle. It can be understood that the cross-sectional shape of the cooler 3 shown in FIG. 2 being a rectangle is merely exemplary.

In FIG. 2, there is a gap between the cooler 3 and a side wall of the groove 2. In an exemplary embodiment, the size of the gap is not particularly limited, as long as the cooler 3 does not fall from the groove 2.

In an exemplary embodiment, the cooler 3 may be a cooling tube, wherein the cooling tube is filled with a cooling liquid for cooling the member to be evaporated 20.

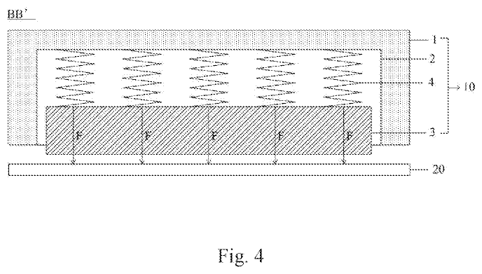

FIG. 4 is a cross-sectional view of the carrier plate 10 taken along line BB′ of FIG. 1 in accordance with another embodiment of the present disclosure. For facilitating to illustrate another embodiment of the present disclosure, FIG. 4 shows the member to be evaporated 20 disposed opposite to the carrying surface of the carrier plate 10. FIG. 4 differs from FIG. 3 in that an elastic element 4 is disposed between the cooler 3 and the bottom of the groove 2.

In an exemplary embodiment, the elastic element 4 may be a spring.

The present disclosure does not specifically limit the length of the elastic member 4 in the maximum compression state and the size of the cooler 3 in a direction from the bottom of the groove 2 toward the outside, as long as the member to be evaporated 20 is closest to the carrier plate 10 and the cooler 3 protrudes outward from the carrying surface of the substrate 1. In an exemplary embodiment, the degree of protrusion is not specifically limited without affecting the flatness and deformation of the member to be evaporated 20, as long as the member to be evaporated 20 can be brought into contact only with the cooler 3 and the contacting area is as small as possible.

As shown in FIG. 4, when the member to be evaporated 20 being separated from the carrier plate 10, the elastic member 4 provides a downward force F, thereby separating the member to be evaporated 20 from the carrier plate 10, so as to prevent from generating static electricity which may cause that the member to be evaporated 20 may not be separated from the carrier plate 10. In an exemplary embodiment, the member to be evaporated may be separated from the carrier plate either manually or automatically.

In the embodiment of the present disclosure, the cooler protrudes outward from the carrying surface of the carrier plate, which can reduce the contacting area of the member to be evaporated with the cooler, thereby reducing the generation of static electricity. In addition, the cooler is in direct contact with the member to be evaporated, such that the temperature of the member to be evaporated can be more effectively controlled. Further, an elastic member is disposed between the cooler and the bottom of the groove, so as to provide a downward force to the member to be evaporated when the member to be evaporated being separated from the carrier plate, thereby ensuring that the member to be evaporated cannot be absorbed to the carrier plate due to the reasons such as static electricity, etc.

In an embodiment of the present disclosure, there is also provided an evaporating device including the above carrier plate. It is possible to reduce the generation of static electricity during the evaporating process.

The foregoing description of the embodiments has been provided for purpose of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are included within the scope of the disclosure.

1. A carrier plate for an evaporating device, the carrier plate comprising:
a substrate comprising a groove on a surface of a side, for carrying a member to be evaporated, of the substrate; and
a cooler disposed within the groove,
wherein the cooler protrudes outward from the surface of the substrate.

2. The carrier plate according to claim 1, wherein a cross-sectional shape of the groove in a direction perpendicular to an extending direction of the groove is a rectangle.

3. The carrier plate according to claim 2, wherein the groove extends in an S-shape.

4. The carrier plate according to claim 3, wherein the groove extends uniformly throughout the surface of the substrate in a zigzag way.

5. The carrier plate according to claim 1, wherein the carrier plate further comprises an elastic element located between the cooler and a bottom of the groove.

6. The carrier plate according to claim 5, wherein the elastic element comprises a spring.

7. The carrier plate according to claim 1, wherein a cross-sectional shape of the cooler in a direction perpendicular to an extending direction of the cooler is one of a rectangle and a circle.

8. The carrier plate according to claim 1, wherein the cooler is a cooling tube.

9. An evaporating device comprising the carrier plate according to claim 1.

10. The evaporating device according to claim 9, wherein the member to be evaporated comprises a glass substrate.

11. An evaporating device comprising the carrier plate according to claim 2.

12. An evaporating device comprising the carrier plate according to claim 3.

13. An evaporating device comprising the carrier plate according to claim 4.

14. An evaporating device comprising the carrier plate according to claim 5.

15. An evaporating device comprising the carrier plate according to claim 6.

16. An evaporating device comprising the carrier plate according to claim 7.

17. An evaporating device comprising the carrier plate according to claim 8.
